(19) United States
(12) Patent Application Publication
(10) Pub. No.: US 2010/0032144 A1
(43) Pub. Date: Feb. 11, 2010

(54) HEAT DISSIPATION DEVICE

(75) Inventors: JIAN YANG, Shenzhen City (CN); HENG LIU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/398,968

(22) Filed: Mar. 5, 2009

(30) Foreign Application Priority Data
Aug. 8, 2008 (CN) 200810303625.X

(51) Int. Cl. F28D 21/00; H05K 7/20

(52) U.S. Cl. 165/121; 361/679.47

(57) ABSTRACT

A heat dissipation device comprises a heat sink, a fan located over the heat sink, a fan holder sandwiched between the heat sink and the fan and a plurality of fasteners fixing the fan holder on the heat sink and the heat sink on a printed circuit board. The fan holder comprises a square plate defining a ventilating hole in a center thereof, four locating plates extending downwardly from four outer edges of the plate and four locating portions extending upwardly at four corners of the plate. Each locating portion partially encircles a corresponding fastener. The fan holder is made of plastic.

### BACKGROUND

1. Field of the Invention

The present disclosure generally relates to a heat dissipation device and, more particularly, to a heat dissipation device having a fan holder sandwiched between a heat sink and a fan thereof.

2. Description of Related Art

It is well known that, during operation of a computer, electronic devices such as central processing units (CPUs) frequently generate large amounts of heat. The heat must be quickly removed from the electronic device to prevent it from becoming unstable or being damaged. Typically, a heat sink is attached to an outer surface of the electronic device to absorb heat generated by the electronic device. The heat absorbed by the heat sink is dissipated to ambient air only by natural heat convection. Therefore, an efficiency of the heat sink is low and difficult to meet a heat-dissipating demand of the electronic device. Conventionally, a fan is secured to a top portion of the heat sink to help the heat sink dissipating the heat generated by the electronic device. The fan blows a forced airflow toward the heat sink to thereby improve the efficiency of the heat sink by forced heat convection.

However, the fan may have a vibration or shock when it is operating. Because of the fan directly attached to an outer surface of the heat sink, the vibration or shock generated by the fan would act directly on the heat sink to thereby produce a big noise.

What is needed, therefore, is heat dissipation device having a fan holder sandwiched between a heat sink and a fan thereof to decrease the noise generated by the fan and the heat sink.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an exploded, isometric view of a heat dissipation device in accordance with an embodiment of the present disclosure, together with an electronic device mounted on a printed circuit board and a back plate located at a bottom of the printed circuit board.

FIG. 2 is a view similar to FIG. 2, but viewed from an inverted aspect.

FIG. 3 is an assembled view of the heat dissipation device of FIG. 1.

### DETAILED DESCRIPTION

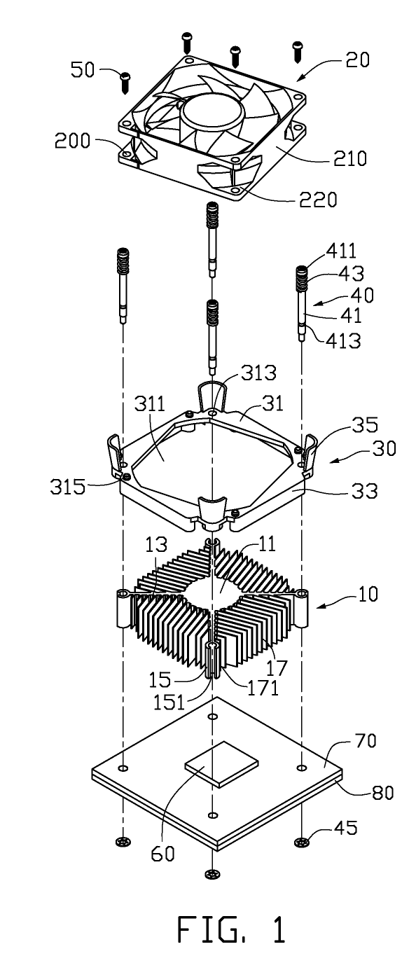

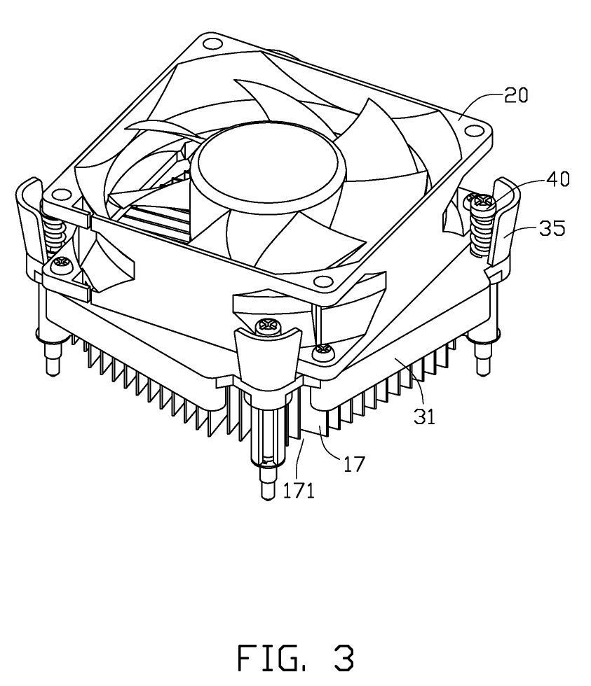

As shown in FIGS. 1-3, a heat dissipation device in accordance with an embodiment of the present disclosure is adapted to dissipate heat generated by an electronic device 60 mounted on a printed circuit board 70. The heat dissipation device includes a heat sink 10, a fan 20 located over the heat sink 10, a fan holder 30 sandwiched between the heat sink 10 and the fan 20 and four fasteners 40 fixing the fan holder 30 on the heat sink 10 and fixing the heat sink 10 to the printed circuit board 70 so that a bottom face of the heat sink 10 can have an intimate contact with a top face of the electronic device 60. Thus, heat generated by the electronic device 60 can be effectively absorbed by the heat sink 10.

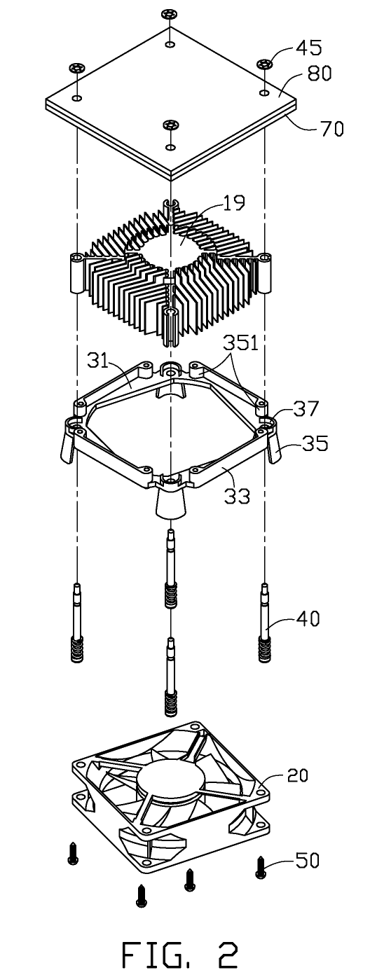

Referring to FIGS. 1-2, the heat sink 10 has a square configuration, and is integrally made of metal such as aluminum by extrusion. The heat sink 10 includes a central core 11, four symmetrical and straight branches 13 radially extending outwardly from a periphery of the core 11 and a plurality of fins 17 extending from the core 11 and the branches 13. The core 11 has a cylindrical configuration. The core 11 includes four outer side surfaces (not labeled) separated by the four branches 13, respectively. Inward extensions of the branches 13 meet at a center of the core 11. Each branch 13 has a height substantially the same as that of the core 11 and includes two opposite side surfaces (not labeled). The four outer side surfaces of the core 11 and the side surfaces of the four branches 13 cooperatively define four heat-dissipating regions (not labeled). A plurality of fins 17 extends outwardly from the side surfaces of the core 11 and the branches 13. The fins 17 are parallel to each other in two opposite regions, and perpendicular to each other in two neighboring regions. Two adjacent and parallel fins 17 close to a distal end of each branch 13 are shorter than other parallel fins 17 in a same region, whereby a notch 171 is defined between the distal end of each branch 13 and the other parallel fins 17. The other parallel fins 17 in each region have ends coplanar in a vertical orientation. A thickness of each branch 13 is gradually decreased along a direction away from the core 11. Four protrusions 15 extend outwardly from extremities of the four branches 13, respectively. Each protrusion 15 has a C-shaped configuration with a cutout (not labeled) defined at an outmost portion thereof. Each protrusion 15 defines a through hole 151 in a center thereof communicating with the cutout. The core 11 and parts of the parallel fins 17 and the branches 13 near the core 11, extend downwardly thereby form a cylindrical step 19 at a bottom of the heat sink 11 for intimately contacting the electronic device 60.

Referring to FIGS. 1-3, the fan holder 30 is integrally formed by plastic. The fan holder 30 includes a substantially square flat plate 31 defining a ventilating hole 311 in a center thereof, four locating plates 33 extending downwardly from four outer edges of the flat plate 31 and four locating portions 35 extending upwardly from four corners of the flat plate 31. The ventilating hole 311, which has an approximate square configuration, has four corners staggered with the four corners of the flat plate 31. Four threaded holes 315 are defined in the flat plate 31 at positions corresponding to the four corners of the ventilating hole 311, allowing four screws 50 to be engaged therein. The flat plate 31 defines four extending holes 313 corresponding to the through holes 151 of the heat sink 10 at the four corners thereof. The four extending holes 313 are partially encircled by the locating portions 35, respectively. Each locating portion 35 has an arc-shaped configuration and is inclined outwardly away from an axis of a corresponding fastener 40 along an upward direction. The locating portion 35 is provided for preventing a tool acting on the fastener 40 from escaping from the fastener 40 to carelessly damage the printed circuit board 70 during assembling of the heat dissipation device to the printed circuit board 70. A substantially arc-shaped resisting piece 37 (see FIG. 2) opposite to a corresponding locating portion 35 extends downwardly from a bottom face of the flat plate 31 for abutting against a circumferential periphery of a corresponding protrusion 15 of the heat sink 10. Each locating plate 33 is spaced from two corresponding resisting pieces 37 located at two opposite ends thereof. Each locating plate 33 forms two tabs 351 extending inwardly from the two opposite ends thereof. The two tabs 351 are received in corresponding notches 171 of the heat sink 10 to thereby preposition of the fan holder 30 with the heat sink 10 before the fasteners 40 are used to secure the fan holder 30 to the heat sink 10 and the heat sink 10 to the printed circuit board 70.

Referring to FIG. 1, each fastener 40 includes a shaft 41 having a head 411 at a top end thereof and defining an annular slot 413 at a bottom end thereof, and a helical spring 43 coiled around the shaft 41 between the head 411 and the annular slot 413. After the fastener 40 extends through the extending hole 313 of the fan holder 30 and the through hole 151 of the heat sink 10, a retaining collar 45 is provided to snap the shaft 40 at the annular slot 413 to assemble the heat sink 10 and the fan holder 30 together. To secure the heat sink 10 to the printed circuit board 70, the fasteners 40 are driven by the tool, for example, a screwdriver to move downwardly through the printed circuit board 70 to threadedly engage with a back plate 80 at a bottom of the printed circuit board 70. The fasteners 40 are partially encircled by the locating portions 35, whereby the screwdriver can be guided by the locating portions 35 to precisely drive the fasteners 40 downwardly to engage with the back plate 80.

The fan 20 includes a rectangular frame 210. The frame 210 includes a pair of parallel plates 220. Four locating holes 200 are defined through the two plates 220 at four corners of the frame 210, respectively. The screws 50 extend through the four locating holes 200 and are engaged in the four threaded holes 315 of the flat plate 31 to thereby fasten the fan 20 on the fan holder 30.

In assembly of the heat dissipation device, the extending holes 313 of the fan holder 30 are positioned in alignment with the through holes 151 of the heat sink 10. The tabs 351 of the locating plates 33 are correspondingly received in the notches 171 of the heat sink 10, and each tab 351 abuts against the fin 17 at a side of a corresponding notch 171. Each resisting piece 37 abuts against an upper circumferential periphery of a corresponding protrusion 15 of the heat sink 10. Then the fan holder 30 is prepositioned at the top surface of the heat sink 10. The four fasteners 40 are brought to extend sequentially through the extending holes 313 of the fan holder 30 and the through holes 151 of the heat sink 10. The helical spring 43 which is sleeved on the shaft 41 beforehand, is sandwiched between the head 411 of the fastener 40 and the flat plate 31. A pressure is exerted downwardly on the head 411 of each fastener 40 to make the slot 413 of the shaft 40 further extending beyond the bottom of the heat sink 10. At the same time, the retaining collar 45 is brought to be received in the slot 413 of the fastener 40 so that the fasteners 40 firmly fasten the fan holder 30 and the heat sink 10 together via a force generated by the helical spring 43. The locating holes 200 of the fan 20 are positioned in alignment with the threaded holes 315 of the fan holder 30. The screws 50 are brought to extend through the locating holes 200 and into the threaded holes 315, thereby fixing the fan 20 on the fan holder 30. At this fixed position, four corners of the fan 20 are staggered with corresponding locating portions 35 of the fan holder 30. To fasten the heat sink 10 to the printed circuit board 70, as disclosed above, the fasteners 40 are driven downward by the screwdriver to theadedly engage with the back plate 80 at the bottom of the printed circuit board 70.

The fan holder 30 made of plastic is sandwiched between the fan 20 and the heat sink 10, whereby a collision acting on the heat sink 10 from the fan 20 due to vibration or shock, can be relieved by the fan holder 30. Accordingly, a noise of the heat dissipation device is decreased.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation device comprising:
a heat sink;
a fan located over the heat sink; and
a plastic fan holder sandwiched between the heat sink and the fan for securing the fan to the heat sink, the fan holder comprising a plastic plate located between the heat sink and fan and a plurality of locating portions extending upwardly from corners the plate;
wherein a plurality of fasteners extends through the plate and the heat sink for securing the fan holder to the heat sink and for securing the heat sink to a printed circuit board, and each of the fasteners is partially encircled by a corresponding locating portion.

2. The heat dissipation device as claimed in claim 1, wherein each of the locating portions has an arc-shaped configuration.

3. The heat dissipation device as claimed in claim 2, wherein each of the locating portions is gradually inclined outwardly away from an axis of a corresponding fastener along an upward direction.

4. The heat dissipation device as claimed in claim 1, wherein a ventilating hole is defined in a center of the plate, and the ventilating hole has a square configuration.

5. The heat dissipation device as claimed in claim 4, wherein the plate has a square configuration.

6. The heat dissipation device as claimed in claim 5, wherein each corner of the ventilating hole is staggered with a corresponding corner of the plate.

7. The heat dissipation device as claimed in claim 6, wherein four threaded holes corresponding to four corners of the ventilating hole are defined in the plate and staggered with the locating portions, respectively.

8. The heat dissipation device as claimed in claim 7, wherein the fan comprises a frame comprising a lower plate defining a plurality of locating holes, a plurality of screws extending through the locating holes and engaging in the four threaded holes to thereby fasten the fan on the fan holder.

9. The heat dissipation device as claimed in claim 1, wherein four locating plates extend downwardly from four outer edges of the plate, and each of the four locating plates forms two tabs extending inwardly from two opposite ends thereof.

10. The heat dissipation device as claimed in claim 9, wherein the heat sink comprises a central core, a plurality of branches radially extending outwardly from vertical edges of a periphery of the core and a plurality of fins extending from the core and the branches.

11. The heat dissipation device as claimed in claim 10, wherein a plurality of regions is cooperatively defined by the core and the branches, and in each region, every two adjacent fins close to corresponding branches are shorter than other fins to thereby form two notches, the two tabs on each locating plate of the fan holder being received in the two notches, respectively.

12. The heat dissipation device as claimed in claim 11, wherein each tab abuts against a fin located at a side of a corresponding notch.

13. The heat dissipation device as claimed in claim 12, wherein a plurality of protrusions extends outwardly from extremities of the branches, respectively, and each protrusion has a C-shaped configuration with a cutout defined in an outmost portion thereof.

14. The heat dissipation device as claimed in claim 13, wherein each protrusion defines a through hole in a center thereof communicating with the cutout thereof.

15. The heat dissipation device as claimed in claim 13, wherein a resisting piece opposite to a corresponding locating portion extends downwardly from a bottom face of the plate, and abuts against a circumferential periphery of a corresponding protrusion of the heat sink.

16. The heat dissipation device as claimed in claim 15, wherein each resisting piece is located between two corresponding adjacent locating plates.

17. The heat dissipation device as claimed in claim 11, wherein the fins in two opposite regions are parallel to and spaced from each other, the fins in two neighboring regions are perpendicular to each other, and the other fins in each region have ends located in a vertical plane.

18. A heat dissipation device comprising:
a heat sink;
a fan located over the heat sink; and
a plastic fan holder sandwiched between the heat sink and the fan, the fan holder comprising a plate and a plurality of locating portions located at corners of the plate, wherein the corners of the fan holder are staggered with those of the fan;
wherein a plurality of fasteners extends through the plate and the heat sink, and each of the fasteners is partially encircled by a corresponding locating portion.
